(19) United States
(12) Patent Application Publication
(10) Pub. No.: US 2012/0235182 A1
(43) Pub. Date: Sep. 20, 2012

(54) Light-Emitting Diode Module and Corresponding Manufacturing Method

(75) Inventors: Juergen Knaus, Jennersdorf (AT); Hannes Tauterer, Ottendorf (AT); Martin Werkovits, Jennersdorf (AT)

(73) Assignee: Tridonic Jennersdorf GmbH, Jennersdorf (AT)

(21) Appl. No.: 13/509,195

(22) PCT Filed: Jun. 16, 2010
(86) PCT No.: PCT/EP2010/058482

§ 371 Date: Jun. 1, 2012

(30) Foreign Application Priority Data
Nov. 13, 2009 (EP) 09175958.9
Dec. 14, 2009 (EP) 09179014.7

(51) Int. Cl. H01L 33/52; H01L 33/58; H01L 33/50

(52) U.S. Cl. 257/88; 438/28; 438/27; 257/E33.059; 257/E33.061; 257/E33.068

(57) ABSTRACT

A new manufacturing method is described by the present invention for a new LED module 1. The method comprises mounting of at least one LED 3 onto a surface of a substrate 2, and depositing a base layer 5 to cover said substrate 2 surface and the LED 3, wherein the base layer 5 is transparent for visible light and preferably does not comprise phosphor particles. Optionally, a first heat treatment to modify the surface properties of the base layer 5 is comprised. The method further comprises dispensing a matrix material, so that it forms an essentially half-spherical cover covering the LED and optionally nearby portions of the base layer, and optionally, a second heat treatment to harden the half-spherical cover layer. Additionally the present invention discloses an LED module 1, which is manufactured by the claimed method.

The invention discloses a light-emitting diode (LED) module and a corresponding manufacturing method. In particular the invention discloses an LED module applying an essentially half-spherical cover layer (“globe-top”) covering the LED chip and the method for covering the LED chip with the globe-top.

LEDs disposed on a LED module are usually covered or packaged to prevent them from becoming damaged or contaminated while shipping, installing and operating. Several packaging or covering methods have been employed to cover LEDs in a module, like plastic molding, liquid filling or the so-called globe-top method.

The globe-top method is usually used for a chip-on-board assembly of the LED chips, where a plurality of LED chips is attached to a substrate and the LEDs are electrically connected to the substrate. The globe-top is a drop of a specially formulated resin, which is deposited over the LED chip on the substrate and the attached wire bonds. The globe-top protects the LED chip beneath, provides mechanical support, and excludes containments or dirt, which could disturb the functionality of the LED circuitry.

When using the globe-top technique to cover LEDs on a substrate, either transparent materials or materials which include phosphor particles are chosen. For example to create white light, e.g. blue LEDs are attached to the substrate and are covered with a globe-top which comprises phosphor material. When the light emitted from the LED excites the phosphor material, the phosphor material emits light in a different wavelength range. The combination of the LED wavelength and the wavelength emitted from the phosphor material creates light, which appears white to the human eye, if the appropriate phosphor material(s) is chosen.

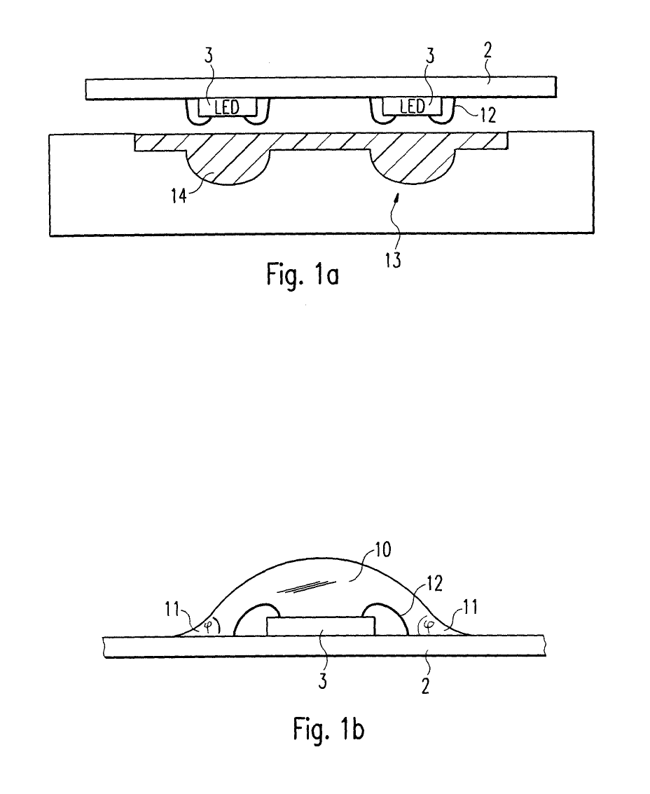

In state of the art, half-spherical cover layers, so-called globe-tops are usually realized by a so-called overmoulding process. FIG. 1 a shows an example of how the overmoulding process is performed. One or more LED chips 3 are mounted to a substrate 2 and are electrically connected to the substrate via wire bonds 12. A globe-top, usually made of silicone material(s), is deposited over each LED, directly onto the substrate. Therefore, an overmoulding form 13, which comprises at least one cavity, which is filled with a resin 14, is positioned to the substrate, so that the resin-filled cavity is positioned directly over the LED chip 3. By thermal processing, while the overmoulding form 13 is pressed to the substrate 2, the resin 14 is hardened and the overmoulding form 13 can be removed. The resin 4 remains attached to the substrate 2 in a half-spherical shape resembling the cavities of the overmoulding form 13, and covers the LED chip 3 and nearby parts of the substrate 2.

However, such an overmoulding process exhibits various disadvantages. First of all, overmoulding machines are expensive. Thus the price per manufactured LED module is relatively high. Secondly, during the pressing of the overmoulding form towards the substrate, deformations or damages of the bonding wire and/or of the LED attached to the substrate can occur. Thereby, the yield of the manufacturing process for the LED modules is decreased. Further luminescent particles (phosphors) cannot be incorporated into the cover layer according to the well-known overmoulding process due to the applicable materials and/or process steps. The application of the well-know overmoulding technique is generally limited to large LED units, while usage of the invented manufacturing technique does not depend on the size of the LED module.

A state of art LED module with a dispensed globe-top is shown in FIG. 1b. A LED chip 3 is mounted to a substrate 2, and a dispensed globe-top 10 is disposed to cover the LED chip 3. The interface angle φ at the interface 11 between the substrate 2 and the globe-top 10 is much smaller than 90°. Due to the differences in surface energies, viscosities and/or wetting properties the globe-top 10 is broadened (flattened) at its outer edges at said interface 11.

The disadvantage when using the state of the art dispensing process is that the substrate and the globe-top, which is usually made of silicone, have different surface energies. As a consequence the half-spherical globe-tops cannot be disposed to cover the LEDs in such a way, that the interface angle between the substrate and the globe-top is close to 90°.

The smaller than 90° interface angle φ degrades the emission characteristics of the LED module. Especially emission characteristics in respect to emission angles are not homogenous. When creating white LEDs, this can lead to disturbing inhomogeneities in color temperature of an LED module depending on the viewing angle.

Therefore, the object of the present invention is to overcome the disadvantages mentioned above. In particular, it is the object of the present invention to provide a low priced method of manufacturing LED modules, which increases the manufacturing yield and improves the emission characteristics of said modules. In particular, the object is to provide a manufacturing method and the corresponding LED module, which applies the dispensing globe-top technique, but supports the formation of an interface angle of preferably 90°, more preferably 82-90°.

The objective problems are solved by the independent claims of the present invention.

A manufacturing method according to the present invention produces a light emitting diode module preferably producing white light. The method comprises the steps of: mounting at least one LED onto a surface of a substrate, depositing a base layer to cover said substrate surface and the LED, wherein the base layer is transparent for visible light and preferably does not comprise phosphor particles, optionally, a first heat treatment to modify the surface properties of the base layer, dispensing a matrix material, so that it forms an essentially half-spherical cover (globe-top) layer covering the LED and optionally nearby portions of the base layer, and optionally, a second heat treatment to harden the half-spherical cover layer.

Preferably, the base layer, at least after the treatment, and the matrix material of the essentially half-spherical cover layer have equal or at least comparable surface energies.

Preferably, the base layer and the matrix material of the globe-top have significantly different viscosities prior to dispensing.

With the manufacturing method according to the present invention, a cheaper solution is achieved. In contrast to the state of the art overmoulding process, no overmoulding machine and overmoulding form, which are very expensive, have to be built or bought. Thereby, the cost per LED module can be significantly decreased. Further, since no overmoulding form has to be pressed onto the LED during the manufacturing process, damage can be avoided and the yield of the LED modules is improved. Especially, operation failure rate due to bonding wire breakage or its loose connection is significantly decreased. Finally, by applying the base layer, the depositing step of the cover layer produces half-spherical shapes with interface angles close to 90°. It's taken an advantage of the application of nearly perfect half-spherical globe-tops applied on the LED modules to improve their emission characteristics.

LED modules produced according to the method of the present invention differ structurally from LED modules manufactured according to the known overmoulding process. The well-known overmoulding process results in formation of LED modules coated by cover layers with nearly monodisperse interface angle distributions. In contrast, the invented method leads to fabrication of LED modules with broader interface angle distributions, while said distribution is comparable to the ones formed by application of the state of art dispensing technique without the invented additional base layer. Additionally, the usage of the invented manufacturing method results in cover layers (globe-tops) with larger interface angles in the range of 82-90°, which are closer to the ideal 90°, in comparison with the well-known dispensing technique, where interface angles about 53-58° are formed.

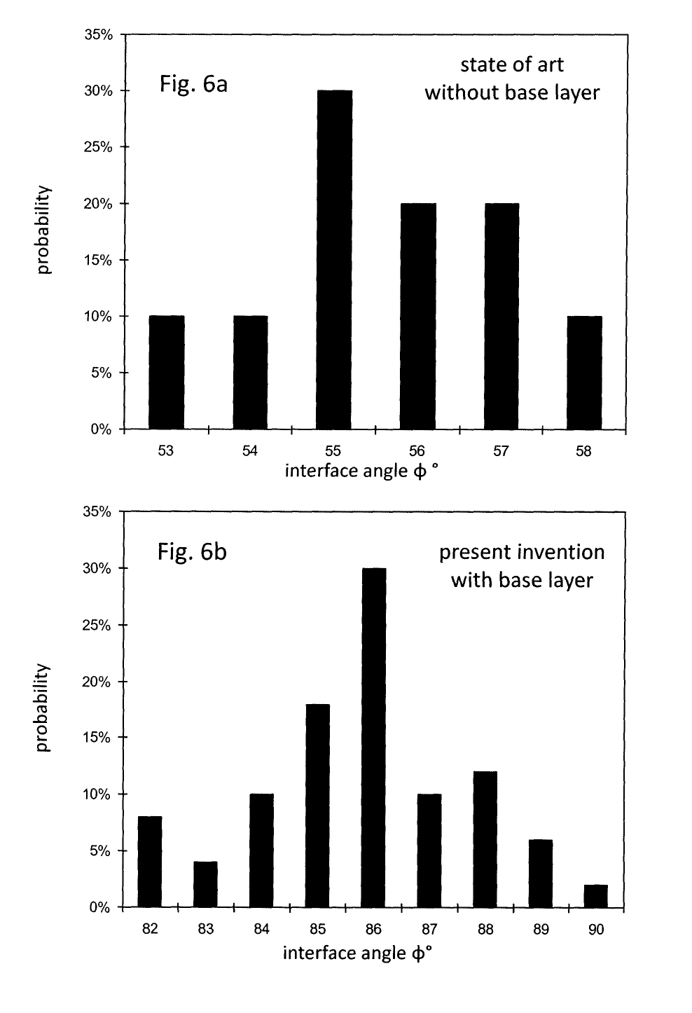

A comparison of the interface angles φ achieved with a state of art dispensing technique and the manufacturing method of the present invention can be learned from two bar diagrams in FIGS. 6a and 6b, respectively. In FIG. 6a the distribution of state of art interface angles φ (as indicated in FIG. 1b) is shown. The x-axis of the bar diagram shows the range of all interface angles φ. The y-axis shows the probability (percentage) for each interface angle φ. The state of art technique produces a range of only about 53°-58°, with a maximum at about 55°.

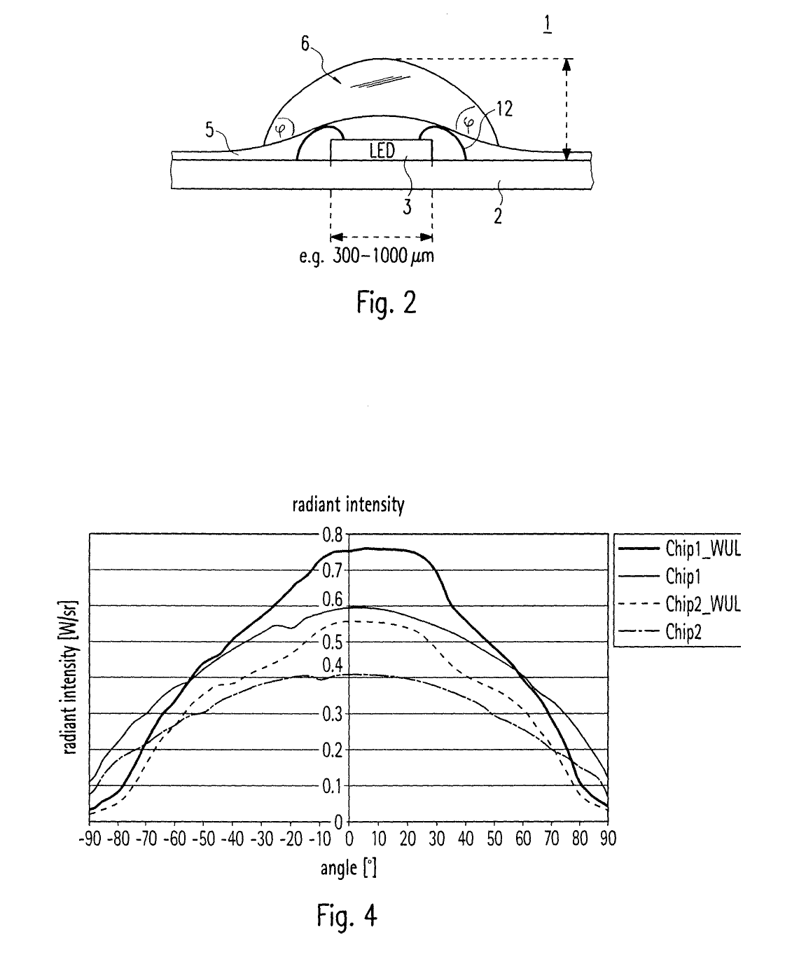

The distribution of the interface angles φ obtained with the method according to the present invention (as indicated in FIG. 2, which is explained in detail later) is illustrated in FIG. 6b. The x-axis and y-axis correspond to FIG. 6a. Due to the additional base layer, the method produces interface angles φ in a range of 82°-90°, with a maximum at 86°.

Furthermore, the base layer of the LED module generated according to invented method is a visible highly transparent surface layer. Especially in a side view, the base layer covering the LED chip will show slowly ascending, flat edges. A thin layer surrounding the globe-tops formed by the overmoulding process can be observed by comparing the shape of the cavity of the overmoulding form in FIG. 1a, as well. Due to the manufacturing process steps, said layer is generated by the same material as the globe-tops. An advantage can be taken by choosing different materials for the fabrication of the cover and base layers according to the invented manufacturing method.

Preferably the step of depositing the base layer is a single-step, e.g. realized by dip-coating or spin-coating. Other known coating techniques like spraying could be applied as well.

The manufacturing process is shortened, which reduces the costs per LED module. Additionally, the generated base layer has a relatively homogenous thickness.

Preferably the step of depositing the base layer is a multi-step, in which small droplets of the base layer material are dispensed in consecutive steps.

Thereby, the base layer can be produced more thoroughly, and possible voids or other defects are avoided. Moreover, the amount of base layer material can be individually varied for each droplet, for example for covering the substrate and for covering the LED chip, where a higher amount of base layer material might be required.

Preferably the step of depositing the base layer comprises a step of incorporating filler particles, e.g silica, alumina, titania, zirconia, barium titanate and/or barium sulphate, into the base layer material.

The cover layer can comprise the filler particles mentioned above, as well. Filler particles modify the rheological properties of the base and/or cover layer. Additionally, they influence the mechanical and/or structural properties of applied layers after thermal treatment(s). The depositing steps of the base and/or cover layers can thus be optimized, for examples in terms of speed and/or yield.

Preferably the viscosity of the base layer material is in a range of 1 Pa·s to 4 Pa·s at a shear rate of 0.94 s⁻¹.

This value is optimal for the depositing step in terms of speed and yield. Regarding the targeted surface coverage, its thickness and homogeneity, the indicated viscosity range, which presents excellent flowability, is chosen.

Preferably the first heat treatment step is performed at approximately 80° C. for approximately 1 hour.

Preferably the second heat treatment step is performed at approximately 150° C. for approximately 1 hour.

Preferably the cover layer material is dropped onto the LED and nearby portions of the base layer.

Dropping of the cover layer material is resulted in the formation of half-spherical shaped globe-tops with excellent emission properties.

Preferably the viscosity of the cover layer material is in a range of 40 Pas·to 85 Pas·at a shear rate of 0.94 s⁻¹.

The value is an optimum for the depositing step in terms of speed and yield.

Preferably, the matrix material comprises phosphor and/or scattering particles.

Preferably, the first and second heat treatments steps can be after formation of the base and/or cover layer applied.

Preferably, the LED chip is a monochromatic and/or a thin phosphor film covered LED chip.

If the LED chip is a monochromatic LED chip and the matrix material comprises no phosphor particles, a monochromatic LED module is obtained. By applying different monochromatic light emitting LEDs a white light emitting LED module can be generated. If the matrix material comprises phosphor particles, a white light emitting LED module can be obtained even with a monochromatic LED. A further possibility to achieve a white light emitting LED module is to use thin phosphor film covered LEDs. In this case the matrix material can optionally comprise additional phosphor particles. Such thin film phosphor-converted light emitting diode devices are known e.g. from U.S. Pat. No. 6,696,703, U.S. Pat. No. 6,501,102 and U.S. Pat. No. 6,417,019 the teaching of which is incorporated by reference as far as it regards the thin film phosphor technology, including its manufacturing, disclosed in these documents.

A light emitting diode module preferably producing white light according to the present invention is obtainable by a method as described by the steps above. The light emitting diode module can be manufactured with monochromatic LEDs and/or thin phosphor film covered LEDs, as described above, and exhibits all mentioned advantages.

A light emitting diode module preferably producing white light according to the present invention comprises a substrate, at least one LED mounted onto a surface of the substrate, a base layer, which is transparent to visible light and preferably does not comprise phosphor particles, covering in close contact said substrate surface and the LED, at least one essentially half-spherical cover layer, which covers the LED and preferably nearby portions of the base layer.

The light emitting diode module exhibits emission characteristics, which are improved over state of the art LED modules. Due to the base layer beneath the cover layer, an interface angle between base layer and cover layer is improved. Due to the resulted more close to half-spherical shaped cover layer, the emission characteristics of the LED module, especially over a range of viewing angles, is improved. Efficiency of the light out-coupling of the LEDs (e.g. thin phosphor film covered LEDs and/or monochromatic LEDs) got significantly increased. For the preferred white light emission, a more homogenous color temperature depending on the viewing angle can be achieved.

Preferably the interface angle between the base layer and the half-spherical cover layer approaches 90°.

An angle of 90° represents a perfect half-sphere. Thus the best emission characteristics for the LED module are possible.

Preferably the substrate is a printed circuit board, PCB.

Preferably the LED is electrically connected to the substrate by at least one bond wire.

The thickness of the base layer is preferably in a range from 100 μm to 500 μm, more preferably in a range from 200 μm to 400 μm.

The above mentioned thickness represents the best compromise between manufacturing costs (thin base layer) and homogeneity of the base layer (thicker base layer).

Preferably the base layer is a two-component silicone resin.

Preferably the cover layer is made of a two-component silicone resin, which can be different from the two-component silicone resin of the base layer.

Preferably the hardness of the cover layer exhibits a Shore-hardness value of preferably 60, and the hardness of the base layer exhibits a Shore-hardness value of preferably 40.

With these hardness values, the best results in terms of a steep interface angle and high mechanical stability of the globe-top are achieved.

Preferably the base layer and/or the cover layer comprise(s) filler particles, e.g. silica, alumina, titania and/or zirconia.

The maximum height of the half-spherical cover layer is preferably in a range from 500 μm to 1400 μm, more preferably in a range from 600 μm to 1300 μm.

The above mentioned height achieves the best emission characteristics and light out-coupling efficiency. Moreover above mentioned half-spheres can be reliably produced in the manufacturing process of the LED module.

The width of the LED is preferably in a range from 300 μm to 1000 μm.

Preferably the at least one essential half-spherical cover layer comprises phosphor particles and/or scattering particles.

Preferably the LED is a monochromatic and/or a thin phosphor film covered LED.

If the LED is a monochromatic LED and the half-spherical cover layer comprises no phosphor particles, a monochromatic LED module is obtained. If the half-spherical cover layer comprises phosphor particles, a white light emitting LED module can be obtained even with a monochromatic LED. Another possibility to achieve a white light emitting LED module is to use thin phosphor film covered LEDs. In this case the half-spherical cover layer optionally can comprise additional phosphor(s).

The present invention will be described in more details below, in reference to the attached drawings, wherein:

FIG. 1a shows a state of the art overmoulding process.

FIG. 1b shows a state of the art LED module with a dispensed and cured, essentially half-spherical transparent cover (“globe-top”).

FIG. 2 shows an LED module according to the present invention.

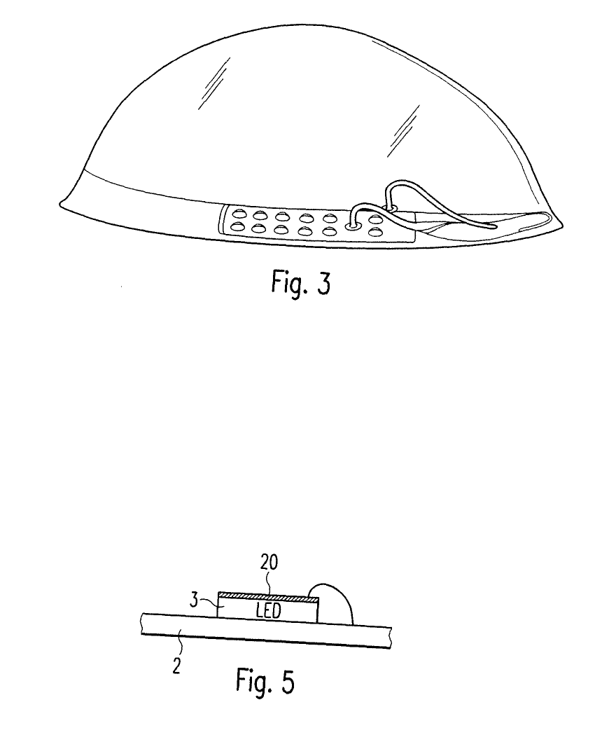

FIG. 3 shows an optical image of an LED module of the present invention.

FIG. 4 shows emission curves of state of the art LED modules and LED modules according to the present invention.

FIG. 5 shows a thin phosphor film covered LED chip.

FIG. 6a shows the distribution of the interface angles for a state of art dispensing technique.

FIG. 6b shows the distribution of the interface angles for a method according to the present invention.

In the following, the LED module and the corresponding manufacturing method are described.

Initially, at least one LED chip 3 is mounted onto a substrate 2. Preferably, the substrate 2 is a printed circuit board (PCB). However, the substrate can also be any kind of substrate, which comprises at least some conducting parts on its surface. This can be realized by metal paths or wiring on the substrate 2 surface. The LED chip 3 is connected electrically via wire bonds 12 to conducting paths on the substrate 2 surface. Preferably special bond pads are present on the substrate 2 surface, onto which the bonding wires 4 can be bonded. The bonding wires 12 are made of a conductive metal, preferably gold. Via the bonds wires 12 the LED chips 3 can be controlled and can be supplied with power.

All available kinds of LED chip(s) 3 or organic LEDs (OLEDs) can be used. The LED chip(s) 3 can be monochromatic and/or can be LEDs coated with a thin phosphor film. A thin phosphor film 20 covered LED chip mounted onto a substrate is shown in FIG. 5. The LED chip 3 is not restricted to a certain color. Preferably, however, blue LED chips are chosen, if the LED module 1 is to emit white light. The power supply of the LED chips 3 can be realized by an AC- or DC-voltage or also an emergency voltage. With the LED chip 3 also a driving circuit can be included to operate the LED chips 3.

In a next step, a base layer 5 is deposited onto the LED chip 3 and onto the substrate 2. The base layer 5 covers at least the complete top surface of the substrate 2 and completely covers the LED chip 3 and also the bond wires 12 (i.e. the bond wires 12, which preferably form an arc with an apex extending higher than the top surface of the LED chip 3, are completely enclosed in the base layer 5).

The base layer 5 is preferably 100 to 500 μm thin, more preferably 200 to 400 μm thin. As shown in FIG. 2, the base layer 5 can have an inhomogeneous thickness, being thicker where the LED chip 3 is positioned in comparison to areas outside the contours of the LED chip 3 (when seen from above).

As base layer 5 material a transparent material is chosen, which preferably shows nearly perfect transmittance over a large wavelength range. The base layer 5 material is at least transparent in the visible wavelength range. The base layer material is preferably a two-component silicone resin. An analysis of the results of the manufacturing method according to the present invention has shown that preferably a short-chain silicone resin is to be used. However, other materials with similar properties can be used. As an example, the silicone resin can be the IVS4312 resin obtainable from ‘Momentive Performance Materials’. IVS4312 is an example for a two-component, transparent, liquid, addition cure silicone resin.

The base layer 5 material preferably shows a low viscosity, to provide excellent flowability during the deposition step. The viscosity of the material at a shear rate of about 0.94 s⁻¹ is between 1 Pa·s and 10 Pa·s. More preferably, the viscosity is between 1 Pa·s and 4 Pa·s.

The base layer 5 can be deposited onto the substrate 2 and the LED chip 3 by either a single step or by multiple steps. In a single step, for example dip-coating or spin-coating of the base layer 5 material onto the substrate 2 and the LED chip 3 is performed. Thereby, both the top and the bottom surface of the substrate 2 are covered with the base layer 5. As an example for multiple steps, dispensing of small droplets of the base layer 5 material in consecutive steps onto the LED chip 3 and substrate 2 can be performed. The procedure is repeated until the complete top surface of the substrate 2 is covered by a continuous base layer 5. The above-mentioned depositing methods are examples and also other methods can be applied, which lead to the same results.

During the depositing of the base layer 5, the base layer 5 material can be provided additionally with filler particles. Filler particles can be used to further adjust the rheological properties of the resin. Rheological properties are for example the flow properties of fluids, or the deformation properties of solids under stress or strain. As filler particles for example silica (SiO₂), alumina (Al₂O₃), titania (TiO₂), and/or zirconia (ZrO) can be used. The filler particles are not incorporated into the purchased silicone resin, but are incorporated into the resin prior to the depositing step of the base layer 5. Especially the viscosity of the base layer 5 can be adjusted more precisely and in a wide range by adding filler particles.

In a next step the base layer 5 can be thermally treated. Thereby the surface properties of the base layer 5 can be modified. During the thermal treatment step(s) cross-linking processes in the applied two-component silicone resins are finalized, while said processes are initiated by mixing the two silicone resin components. Preferably, the heat treatment is performed at 80° C. for one hour.

In a next step at least one essentially half-spherical cover layer (globe-top) 6 is dispensed, so that it covers the LED chip 3 and optionally nearby portions of the base layer 5. Preferably when forming the globe-top 6 a silicone resin is used, and is dropped or dispensed onto the position where the LED chip 3 is located on the substrate 2. The cover layer 6 material is preferably a two-component silicone resin. However, other materials with similar properties can be used. The silicone resin used for the cover layer 6 can be different than the silicone resin used for the base layer 5. As an example, the silicone resin can be the IVS4632 resin obtainable from ‘Momentive Performance Materials’. IVS4632 is a two-component, addition cure silicone resin. A preferred material for the cover layer 6 is XE14, which is a two-component silicone resin.

The cover layer 6 can comprise phosphor particles and/or scattering particles, so as to alter the properties of the light, which is emitted by the LED chip 3. Especially if a white light LED module 1 is constructed, phosphor particles are chosen, which emit in a wavelength range, which combines with the wavelength emitted from the LED chip 3 to a color visible as white light for the human eye. Scattering particles can diffuse the light to achieve a more homogeneous and pleasant light of the LED module 1. In contrast to the cover layer 6, which can comprise phosphor particles, the base layer 5 preferably does not comprise phosphor particles.

During the depositing of the cover layer 6, the cover layer 6 material can be provided additionally with filler particles. Filler particles can be used to further adjust the rheological properties of the resin. Rheological properties are for example the flow properties of fluids, or the deformation properties of solids under stress or strain. As filler particles for example silica (SiO₂), alumina (Al₂O₃), titania (TiO₂), and/or zirconia (ZrO) can be used. The filler particles are not incorporated into the purchased silicone resin(s), but are incorporated into the resin prior to the depositing step of the cover layer 6. Especially the viscosity of the cover layer 5 can be adjusted more precisely and in a wide range by adding filler particles.

The cover layer 6 is disposed onto the LED chip 3, so that the complete LED chip 3 is covered. The width of an LED chip 3 is preferably in a range of 300 to 1000 μm. The width of the cover layer 6 is preferably larger than the width of the LED chip 3, to optionally also cover nearby portions of the base layer 5, which itself is covering the LED chip 3 and the substrate 2. The amount of material of the cover layer 6 is chosen such that the height of the half-spherical cover layer 6 is in a range between 500 to 1400 μm, more preferably in a range from 600 to 1300 μm.

The cover layer 6 material preferably shows rheological properties of a viscosity in a range of 40 to 85 Pa·s at a shear rate of 0.94 s⁻¹. Moreover, a storage modulus of 700 to 1100 Pa is preferred.

As final optional step a heat treatment can be performed at a temperature of 150° C. for one hour, to harden the cover layer 6. In its final, hardened or cured state, the cover layer 6 is preferably harder than the base layer 5. For example, the cover layer 6 can exhibit a dimensionless Shore-hardness A (which is defined on a standardized durometer scale, and is typically used as a measure of hardness in polymers, elastomers and rubbers) of around 50 to 70, preferably 60, while the base layer 5 can exhibit a Shore-hardness of around 20 to 50, preferably 40.

With the above described method, the LED module 1 shown in FIG. 2 can be manufactured. The LED module in FIG. 2 shows the substrate 2, the LED chip 3, the bond wires 4, the base layer 5, which covers the substrate 2 and the LED chip 3, and the half spherical cover layer 6. The half spherical cover layer 6 preferably comprises phosphor particles and/or scattering particles, and covers the LED chip 3 and optionally also nearby portions of the base layer. Preferably, in case more than one LED is disposed inside the LED module 1, each half-spherical cover layer 6 covers one LED. However, the invention is not restricted thereto, and also more than one LED chip 3 can be covered by one half-spherical cover layer 6.

The LED module 1 can be manufactured such, that the interface angle φ between the base layer 5 and the cover layer 6 approaches 90°. This is due to the surface properties of the base layer 5. If, as in state of the art, a globe-top is deposited directly onto the substrate 2, due to the different surface energies of the substrate 2 and the globe-top, interface angles φ of close to 90° cannot be reached. By applying the base layer 5 and optionally modifying the surface properties by use of a thermal process, the interface surface energies become comparable.

Additionally, low viscosity cover layer 6 materials support the generation of nearly half-spherical globe-tops. They are simply more stable in shape prior to and during the second heat treatment process. Thus, an interface angle φ of at least 80°, preferably 85°, and more preferably approaching 90° can be realized. FIG. 3 shows an optical image of the LED module 1. Especially the half-spherical globe-top 6 is clearly visible. It can be observed that the interface angle φ of the half-spherical cover layer 6 and the base layer 5 approaches 90°.

A distribution of the achieved interface angles φ obtained for different LED chips of the LED module 1 is shown in FIG. 6b. Each interface angle cp on the x-axis has an associated probability (percentage), which is measured on the y-axis. FIG. 6b illustrates that interface angles cp with at least 80° can be produced with a probability of almost 100%. An interface angle cp of 86° has the highest probability of about 30%. Even perfect 90° interface angles cp can still be obtained with a probability of about 2%.

The FWHM (Full Width at Half Maximum) value of the interface angle distribution according to the invention is in the order of 2°. Thus the interface angle achieved using the invention is narrowly defined in comparison to known dispensing techniques, as will be evident from the following description of FIG. 6a.

Compared to the state of the art dispensing technique, for which the distribution of interface angles φ is shown in FIG. 6a, the improvement of the method according to the present invention becomes clear. The state of art dispensing technique only yields LED modules with interface angles φ in a range of 53° to 58°.

The FWHM (Full Width at Half Maximum) value according to the prior art is in the order of 4° to 5°.

Due to the improved implementation of the half-spherical globe-top 6, the emission characteristics are improved. The more the globe-tops resemble a perfect half-sphere, the better the efficiency of the light emission becomes. Especially, the efficiency at larger emission angles can be greatly improved.

FIG. 4 shows a comparison of emission curves of LED modules 1 of the present invention and state of the art LED modules comprising simple dispensed globe-top covered LEDs, as shown in FIG. 1b and described above. Two different LED modules 1 have been compared, denominated with Chip1 and Chip2 in the FIG. 4. Thereby, the curves denominated with Chip1_WUL and Chip2_WUL, respectively, are emission curves of LED modules 1 according to the present invention including a base layer 5 and a half-spherical shaped cover layer 6. The curves denominated with Chip 2 and Chip 1 are emission curves of LED modules without a base layer 5 according to state of the art. On the horizontal axis of the graph illustrated in FIG. 4, the emission angle of the emitted light is indicated. With the vertical axis the radiant intensity in units of W/sr is indicated.

It can be clearly observed that the radiant intensity in the whole range is higher for the two LED modules 1 with the additional base layer 5 produced by the method of the present invention. The two emission curves of state of the art LED modules show a lower radiant intensity. Especially in the middle sections of the curve (between emission angles of −5° to) 20°) in comparison with standard state of the art globe-top LED modules, the LED modules 1 according to the present invention show an enhancement of ca. 25% in radiation intensity.

In summary, a new method has been described by the present invention to manufacture a new and inventive LED module 1. By depositing an additional base layer 5, which covers a substrate 2 and at least one LED chip 3, in combination with an optional heat treatment the surface properties of the base layer 5 and the cover layer 6 can be made nearly equal.

Subsequently, a dispensed cover layer 6 in the form of a half-spherical globe-top, which covers the LED 3 and optionally nearby portions of the base layer 5, can be formed in an improved manner. The method does not require the state of the art overmoulding process, which reduces the costs of each LED module, and also improves the yield, because possible damage in the manufacturing process is prevented. The application of the method is resulted in an almost perfectly half-spherical shaped globe-top 6, which significantly improves the efficiency of the light out-coupling of the LED in comparison to the state of art globe-top dispensing technique.

Furthermore, the emission characteristics of the LED module 1 according to the present invention can be enhanced. Especially an angle dependent radiant intensity can be improved. Due to the fact that the formation of improved interface angles φ between the base layer 5 and the cover layer 6 are reachable with the method of the present invention (approaching 90°), a more homogeneous emitted light distribution can be achieved. Especially for white LED modules 1, a more homogeneous color temperature of the white light over a large angle can be realized.

1. Manufacturing method for a LED module (1), preferably producing white light, the method comprising the steps of:
mounting at least one LED chip (3) onto a surface of a substrate (2);
depositing a base layer (5) to cover, preferably in direct contact, said substrate (2) surface and the LED chip (3), wherein the base layer (5) is transparent for visible light and preferably does not comprise phosphor particles;
optionally, a first heat treatment to modify the surface properties of the base layer (5);
dispensing a matrix material, preferably in direct contact onto the base layer (5), so that the matrix material forms an essentially half-spherical cover layer(6) covering the LED chip (3) and optionally nearby portions of the base layer (5), and
optionally, a second heat treatment to harden the half-spherical cover layer (6).

2. Manufacturing method according to claim 1, wherein the step of depositing the base layer (5) is a single-step, e.g. realized by dip-coating or spin-coating.

3. Manufacturing method according to claim 1, wherein the step of depositing the base layer (5) is a multi-step, in which small droplets of the base layer material are dispensed in consecutive steps.

4. Manufacturing method according to claim 1, wherein the step of depositing the base layer (5) or the step of depositing the cover layer (6) comprises a step of incorporating filler particles, e.g silica, alumina, titania and/or zirconia, into the base layer material.

5. Manufacturing method according to claim 1 4, wherein in the step of depositing the base layer (5) the viscosity of the base layer material is in a range of 1 Pa·s to 4 Pa·s at a shear rate of 0.94 s⁻¹.

6. Manufacturing method according to claim 1, wherein in the step of dispensing the cover layer (6) the cover layer material is dropped onto the LED chip (3) and nearby portions of the base layer (5).

7. Manufacturing method according to claim 1, wherein in the step of dispensing the cover layer (6), the viscosity of the cover layer material is in a range of 40 Pa·s to 85 Pa·s at a shear rate of 0.94 s⁻¹.

8. Manufacturing method according to claim 1, wherein the first heat treatment step is performed at approximately 80° C. for approximately 1 hour.

9. Manufacturing method according to claim 1, wherein the second heat treatment step is performed at approximately 150° C. for approximately 1 hour.

10. Manufacturing method according to claim 1, wherein the matrix material comprises phosphor and/or scattering particles.

11. Manufacturing method according to claim 1, wherein the LED chip (3) is a monochromatic and/or a thin phosphor film covered LED.

12. A Light emitting diode module (1) preferably producing white light, obtainable by a method according to claim 1.

13. Light emitting diode module (1) preferably producing white light, comprising
a substrate (2);
at least one LED chip (3) mounted onto a surface of the substrate (2);
a base layer (5), which is transparent to visible light and preferably does not comprise phosphor particles, covering in close contact said substrate (2) surface and the LED (3);
at least one essentially half-spherical cover layer (6), which covers the LED chip(3) and optionally nearby portions of the base layer (5).

14. LED module (1) according to claim 13, wherein an interface angle between the base layer (5) and the half-spherical cover layer (6) is close to 90°, preferably between 82° and 90°.

15. LED module (1) according to claim 13, wherein the thickness of the base layer (5) is preferably in a range from 100 μm to 500 μm, more preferably in a range from 200 μm to 400 μm.

16. LED module (1) according to claim 13, wherein the base layer (5) is a two-component silicone resin.

17. LED module (1) according to claim 13, wherein the cover layer (6) is made of a two-component silicone resin, which is different from the two-component silicone resin of the base layer (5).

18. LED module (1) according to claim 17, wherein the hardness of the cover layer (6) exhibits a Shore-hardness A value of preferably 60, and the hardness of the base layer (5) exhibits a Shore-hardness value of preferably 40.

19. LED module (1) according to claim 13, wherein the base layer (5) and/or the cover layer (6) comprises filler particles, e.g. silica, alumina, titania and/or zirconia.

20. LED module (1) according to claim 13, wherein the maximum height of the half-spherical cover layer (6) is preferably in a range from 500 μm to 1400 μm, more preferably in a range from 600 μm to 1300 μm.

21. LED module (1) according to claim 13, wherein the width of the LED (3) is preferably in a range from 300 μm to 1000 μm.

22. LED module (1) according to claim 13, wherein the at least one essentially half-spherical cover layer (6) comprises phosphor particles and/or scattering particles.

23. LED module (1) according to claim 13, wherein the LED chip (3) is a monochromatic and/or a thin phosphor film (20) covered LED chip.
